(19) United States
(12) Patent Application Publication
(10) Pub. No.: US 2026/0347992 A1
(43) Pub. Date: Nov. 5, 2026

(54) METALIZED FILM, METHOD FOR PRODUCING THE SAME, AND FILM CAPACITOR

(71) Applicant: SHIZUKI ELECTRIC COMPANY INC., Hyogo (JP)

(72) Inventors: Yuki NAGAO, Hyogo (JP); Shinichi KOBAYASHI, Hyogo (JP); Yusuke NOMA, Hyogo (JP)

(73) Assignee: SHIZUKI ELECTRIC COMPANY INC., Hyogo (JP)

(21) Appl. No.: 19/118,479

(22) PCT Filed: Mar. 14, 2024
(86) PCT No.: PCT/JP2024/010098

§ 371 Date: Apr. 4, 2025

(30) Foreign Application Priority Data
Mar. 29, 2023 (JP) 2023-054323

(51) Int. Cl. C23C 14/04; H01G 4/33

(52) U.S. Cl. CPC C23C 14/042; H01G 4/33

(57) ABSTRACT

[Problem] The purpose of the present invention is to improve a metalized film. [Solution] A metalized film using a hydrocarbon-based oil having a 10% vaporization temperature of 237 °C or higher and a 90% vaporization temperature of 337 °C or lower as a masking oil or an after oil. When the hydrocarbon-based oil is used as the masking oil, the contact angle of the hydrocarbon-based oil with respect to a dielectric film is preferably 17.9 to 22.8°. The contact angle of the hydrocarbon-based oil with respect to a polypropylene film is more preferably 17.9 to 22.8°.

### TECHNICAL FIELD

The present invention relates to a metalized film, a method for producing the same, and a film capacitor including the metalized film.

### BACKGROUND ART

In producing a metalized film including a vapor deposition pattern including a vapor deposition portion and a non-vapor deposition portion, a portion to be the non-vapor deposition portion in the surface of a dielectric film is masked in advance, and a metal is then vapor-deposited to form a desired vapor deposition pattern on the surface of the dielectric film.

Examples of a masking method include an oil mask method using an oil as a masking material. Since a metal is not vapor-deposited on a portion to which a masking oil is adhered, a vapor deposition pattern corresponding to the application (adhesion) shape of the masking oil is formed on the surface of the dielectric film.

Meanwhile, in Patent Literatures 1 and 2, a fluorine oil (perfluoropolyether or the like) is used as a masking oil. Since the fluorine oil has good wettability to a film, it is possible to suppress defects (omission: a problem that a metal is vapor-deposited on a portion where the metal is not originally vapor-deposited) caused by insufficient adhesion of the oil to a portion to be masked. Since the thermal stability of the fluorine oil is high and deterioration such as decomposition is less likely to occur at the time of heating, the vaporization is stable, the oil is vaporized and scattered to an unintended portion at the time of metal vapor deposition, and defects (unevenness: a problem that the metal is not vapor-deposited on the portion where the metal should be vapor-deposited or the deposition amount is extremely less) caused by masking to the portion where the metal should be originally vapor-deposited is less likely to occur.

Meanwhile, the fluorine oil is decomposed by an electron beam irradiated at the time of metal vapor deposition in order to improve the adhesion between the dielectric film and a cooling roller to generate fluorine ions, and the deterioration of the vapor-deposited metal is promoted, which becomes a factor of lowering the reliability of a capacitor. Since the fluorine oil is made of fluorocarbon which may cause a load on the environment, the fluorine oil is one of substances that should be avoided from being used.

As the masking oil, a hydrocarbon-based oil may be used, but since the vaporization of the hydrocarbon-based oil is unstable, and the amount of adhesion of the hydrocarbon-based oil to the dielectric film tends to vary, which causes a disadvantage that the frequency of occurrence of unevenness and omission is high.

The vapor-deposited metal is deteriorated by moisture absorption. Therefore, a protective film may be formed by applying a silicone oil as an after oil to a vapor deposition surface.

However, since the silicone oil has a property of easily transmitting water vapor, the moisture absorption of the vapor-deposited metal cannot be sufficiently suppressed.

### CITATIONS LIST

### Patent Literature

Patent Literature 1: JP 63-7363 A
Patent Literature 2: WO 2017/068758 A

### SUMMARY OF INVENTION

### Technical Problems

The purpose of the present invention is to improve a metalized film.

### Solutions to Problems

A metalized film uses a hydrocarbon-based oil having a 10% vaporization temperature of 237 °C or higher and a 90% vaporization temperature of 337 °C or lower as a masking oil or an after oil.

In the metalized film, a contact angle of the hydrocarbon-based oil with respect to a dielectric film is preferably 17.9 to 22.8°. A contact angle of the hydrocarbon-based oil with respect to a polypropylene film is preferably 17.9 to 22.8°.

A film capacitor of the present invention includes any of the metalized films described above.

A method for producing a metalized film of the present invention includes the step of vaporizing and adhering the hydrocarbon-based oil.

### Advantageous Effects of Invention

When a hydrocarbon-based oil having a 10% vaporization temperature of 237 °C or higher and a 90% vaporization temperature of 337 °C or lower is used as a masking oil, an influence on the deterioration of a vapor-deposited metal and an environment load are less. In addition, a metalized film in which the occurrence of unevenness and omission is suppressed is obtained.

When the hydrocarbon-based oil having a 10% vaporization temperature of 237 °C or higher and a 90% vaporization temperature of 337 °C or lower is used as an after oil, the moisture adsorption of the vapor-deposited metal can be suppressed.

### BRIEF DESCRIPTION OF DRAWINGS

FIG. 1 is a view showing the vapor deposition pattern of a film capacitor according to an embodiment of the present invention.

FIG. 2 is a cross-sectional view of the main portion of a metalized film.

FIG. 3 is a cross-sectional view of the main portion of a metalized film to which an after oil is applied.

FIG. 4 is a graph showing the result of a moisture resistance load test.

### DESCRIPTION OF EMBODIMENTS

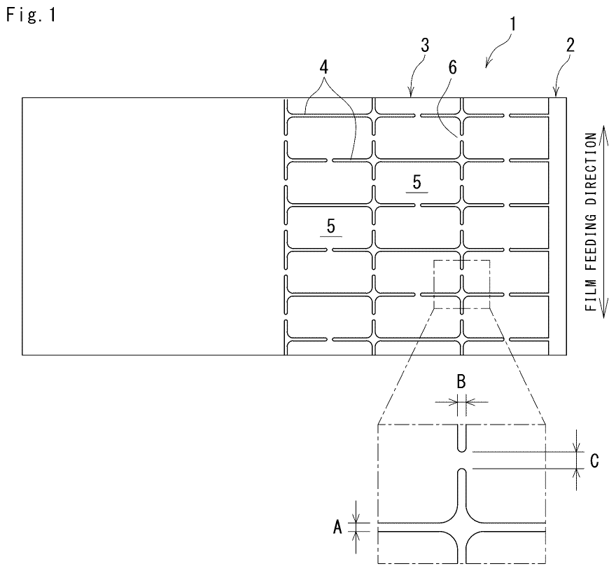

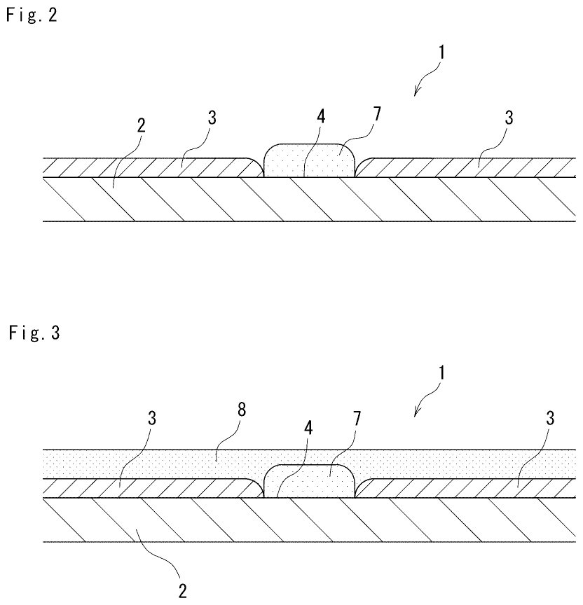

Hereinafter, a film capacitor according to an embodiment of the present invention will be described. As the film capacitor, a metalized film 1 shown in FIGS. 1 and 2 is used. The metalized film 1 includes a vapor deposition pattern including a vapor deposition portion 3 and a non-vapor deposition portion 4 on the surface of a dielectric film 2. The vapor deposition portion 3 refers to a portion on which a metal such as aluminum or zinc is vapor-deposited. The non-vapor deposition portion 4 refers to a portion on which no metal is vapor-deposited. The non-vapor deposition portion 4 is, for example, a margin portion for partitioning the vapor deposition portion. The vapor deposition portion 3 partitioned by the margin portion is a divided electrode 5, for example. The divided electrodes are connected to each other by a fuse portion 6. FIG. 1 shows a portion of the metalized film 1 cut out, and actually continuous in a film feeding direction.

The dielectric film is a synthetic resin film. For example, the dielectric film is a film made of any of polypropylene, polyethylene terephthalate, polyethylene naphthalate, polyphenylene sulfide, polyvinylidene fluoride, and a cycloolefin polymer. In particular, a polypropylene film is preferable, and a biaxially stretched polypropylene film is more preferable. The surface of the dielectric film is preferably subjected to corona treatment. The thickness of the film is not particularly limited, and is, for example, 2.5 μm.

In the meantime, the non-vapor deposition portion is formed by an oil mask method. The masking oil used in the oil mask method is a hydrocarbon-based oil satisfying at least the following condition 1. The masking oil is more preferably a hydrocarbon-based oil satisfying both conditions 1 and 2. Furthermore, the masking oil is more preferably a paraffin oil among hydrocarbon-based oils satisfying both the conditions 1 and 2.

[Condition 1] 10% vaporization temperature: 237 °C or higher, 90% vaporization temperature: 337 °C or lower

When the 10% vaporization temperature is lower than 237 °C, the masking oil is easily vaporized, and unevenness easily occurs. When the 90% vaporization temperature is higher than 337 °C, omission easily occurs.

The vaporization temperature is a numerical value measured by a thermogravimetric measurement method based on JIS K0129 (2005). Specifically, a masking oil as a sample was put in an aluminum container (without a lid) of a thermogravimetry-differential thermal simultaneous measuring device (DTG-60H: manufactured by Shimadzu Corporation). Then, the temperature was increased from room temperature to 600 °C at a rate of 10 °C per minute, and a temperature when the mass of the masking oil decreased by 10% and a temperature when the mass decreased by 90% were measured.

[Condition 2] Contact angle with respect to dielectric film: 17.9 to 22.8°

The “contact angle” is preferably a contact angle with respect to the polypropylene film, more preferably a contact angle with respect to the biaxially stretched polypropylene film, and still more preferably a contact angle with respect to the corona-treated surface of the biaxially stretched polypropylene film.

When the contact angle is less than 17.9°, the masking oil easily spreads beyond the intended range, and unevenness easily occurs. When the contact angle is larger than 22.8°, it is difficult to adhere the masking oil to the dielectric film, and omission easily occurs.

The contact angle is a numerical value measured by a sessile drop method based on JIS R3257 (1999). Specifically, 3±0.5 μL of a liquid is dropped onto a sample with a micro syringe under an air temperature of 25 °C and a humidity of 50%. Then, the sample is allowed to stand, and a droplet is photographed after 1.5±0.1 seconds. The radius r and the height h of the droplet are obtained and substituted into the following formula to obtain the contact angle θ.

$$tan {θ}_{1} = \frac{h}{r} \to θ = 2 arctan \frac{h}{r} \qquad [ Mathematical formula 1 ]$$

The metalized film is produced as follows. First, a masking oil is adhered to the surface of a dielectric film by, for example, a flexographic printing method. Specifically, a letterpress plate including a protrusion having substantially the same shape as that of a non-vapor deposition portion is prepared, and the masking oil is adhered to the letterpress plate. For example, a masking oil stored in an oil tank is first heated using a heat source such as a heater to vaporize the masking oil. Next, the vaporized masking oil is applied to a roll (adhered: vapor deposition step). The roll is pressed against the letterpress plate. Thereafter, the letterpress plate is pressed against the surface of the dielectric film to transfer (adhere) the masking oil. At this time, the masking oil adhered to the protrusion of the letterpress plate is transferred, and a masking oil layer 7 is formed on the dielectric film (see FIG. 2). Meanwhile, the masking oil adhered to the recess of the letterpress plate is not transferred. Therefore, the shape of the transferred masking oil layer 7 is substantially the same as that of the protrusion of the letterpress plate. As a method for adhering the masking oil, in addition to the flexographic printing method, a screen printing method, a gravure printing method, an offset printing method, a spraying method, a die coating method, or the like may be adopted.

Next, a metal is vapor-deposited on the surface of the dielectric film to which the masking oil is transferred. For example, vapor deposition is performed by a vacuum vapor deposition method. Specifically, the dielectric film is placed in a vacuum vapor deposition machine, and a metal is vapor-deposited on the surface subjected to corona discharge treatment so that the film resistance value becomes a predetermined value. The metal is heated by, for example, a resistance heating method. A metal is vapor-deposited on a portion to which the masking oil is not adhered to form a vapor deposition portion. Meanwhile, a metal is not vapor-deposited on a portion to which the masking oil is adhered to form a non-vapor deposition portion. In short, a vapor deposition pattern corresponding to the protrusion shape of the letterpress plate is formed.

A film capacitor of the present invention is produced by winding the metalized film having the above configuration and forming a metallikon electrode formed by spraying, for example, a metal at both axial ends. Note that lamination may be performed instead of winding.

Next, results of comparative inspection of metalized films produced using masking oils different from each other will be described.

### Example 1

A metalized film using, as a masking oil, a hydrocarbon-based oil (paraffin oil) having a 10% vaporization temperature of 237 °C, a 90% vaporization temperature of 317 °C, and a contact angle of 17.9°.

### Example 2

A metalized film using, as a masking oil, a hydrocarbon-based oil (paraffin oil) having a 10% vaporization temperature of 265 °C, a 90% vaporization temperature of 337 °C, and a contact angle of 22.8°.

### Comparative Example 1

A metalized film using, as a masking oil, a hydrocarbon-based oil (paraffin oil) having a 10% vaporization temperature of 215 °C, a 90% vaporization temperature of 295 °C, and a contact angle of 14.3°.

### Comparative Example 2

A metalized film using, as a masking oil, a hydrocarbon-based oil (paraffin oil) having a 10% vaporization temperature of 253 °C, a 90% vaporization temperature of 358 °C, and a contact angle of 27.4°.

A metalized film was produced under the same conditions except that the masking oil was different in each of Examples and Comparative Examples. That is, a biaxially stretched polypropylene film having a length of 8000 m and a thickness of 2.5 μm was used as a dielectric film, and the surface of the biaxially stretched polypropylene film was subjected to corona treatment. A masking oil was adhered to the corona-treated surface by a flexographic printing method, and aluminum was then vapor-deposited to form a predetermined vapor deposition pattern. In the vapor deposition pattern, as shown in FIG. 1, margin portions (non-vapor deposition portions 4) are provided in a lattice shape, and adjacent divided electrodes 5 are connected to each other by fuse portions 6.

As one of inspection items, the presence or absence of occurrence of unevenness (a problem that a metal was not vapor-deposited on a portion where the metal was to be originally vapor-deposited or the vapor deposition amount was extremely less) and omission (a problem that a metal was vapor-deposited on a portion where the metal was not originally vapor-deposited) was confirmed. The unevenness was magnified 20 times with a microscope at a position of initial action 1500 m, and the presence or absence of the unevenness was visually confirmed. Regarding the omission, sampling was performed from the initial action, the middle stage, and the final stage (each N=30), and the omission was magnified 40 times with a microscope to confirm the presence or absence of the omission as compared with a limit sample.

As another inspection item, a width dimension A of a margin portion extending in a direction orthogonal to a film feeding direction, a width dimension B of the margin portion extending in a direction parallel to the film feeding direction, and a width dimension C of a fuse portion provided between the margin portions extending in the direction parallel to the film feeding direction were measured. Regarding the dimensional accuracy, sampling (each N=30) was performed from the initial action, the middle stage, and the final stage, and the dimensions were measured with a microscope at a magnification of 40 times. It was confirmed whether the average value and the standard deviation a of each dimension were within reference values in Table 1. The reference value is dimensional accuracy obtained when a fluorine oil having a 10% vaporization temperature of 235 °C or higher, a 90% vaporization temperature of 335 °C, and a contact angle of 17.9 to 22.8° is used as the masking oil (the other conditions are the same as those in each of Examples and Comparative Examples).

TABLE 1

| | | Dimension A | Dimension B | Dimension C |
|---|---|---|---|---|
| Design value | | 0.200 | 0.100 | 0.100 |
| Average | Lower limit (−5%) | 0.190 | 0.095 | 0.095 |
| value | Upper limit (+5%) | 0.210 | 0.105 | 0.105 |
| σ | Upper limit | 0.015 | 0.015 | 0.015 |

The unit of the average value is mm.

Table 2 shows the inspection results. As can be seen from Table, in Examples 1 and 2, all of the unevenness, the omission, and the dimensional accuracy are equivalent to the references. Meanwhile, in Comparative Example 1, the unevenness is lower than the reference, and in Comparative Example 2, the omission and the dimensional accuracy are lower than the references.

TABLE 2

| | | | | Compar- | Compar- |
|---|---|---|---|---|---|
| | | | | ative | ative |
| | | Example 1 | Example 2 | Example 1 | Example 2 |
| Inspection | Unevenness | ◯ | ◯ | X | ◯ |
| items | Omission | ◯ | ◯ | ◯ | X |
| | Dimensional | ◯ | ◯ | ◯ | X |
| | accuracy | | | | |

◯: Equivalent to the references (fluorine oil is used)
X: Lower than the references

As described above, it can be seen that even in the case of the hydrocarbon-based oil, by specifying the vaporization temperature and the contact angle with respect to the dielectric film, the results not inferior to that in the case of using the fluorine oil can be obtained. The fluorine oil has a problem that the fluorine oil is decomposed by an electron beam irradiated at the time of metal vapor deposition in order to improve the adhesion between the dielectric film and a cooling roller to generate fluorine ions, which promote the deterioration of the vapor-deposited metal, and a problem that the cost of the fluorine oil is high. Meanwhile, in the case of the hydrocarbon-based oil, such a problem is less likely to occur, and an inexpensive and highly reliable film capacitor can be produced.

The applicant has separately confirmed that the life (reduction rate of capacitance when a voltage of 600 VDC is applied in an environment of 105 °C) of the film capacitor using the fluorine oil as the masking oil is substantially the same as that of the film capacitor using the metalized film of Example 1 or Example 2.

Next, a metalized film using a hydrocarbon-based oil as an after oil will be described. The after oil is an oil applied to the vapor deposition surface of the metalized film (the surface on which a vapor deposition portion 3 is formed). The applied after oil forms a protective film 8 on the vapor-deposited metal (vapor deposition portion 3) (see FIG. 3). The protective film 8 is formed, for example, by heating and vaporizing the after oil filled in the oil tank with a heat source such as a heater and adhering the vaporized after oil to the vapor deposition surface. That is, the after oil is applied by vapor deposition in the same manner as the application of the masking oil. However, there is a difference in that the after oil is directly applied, whereas the masking oil is indirectly applied via an inclusion such as a roll or a letterpress plate. In FIG. 3, a boundary is drawn between a masking oil layer 7 and an after oil layer 8, but the layers may be mixed with each other to make the boundary unclear.

The hydrocarbon-based oil used as the after oil satisfies the following condition 1.

[Condition 1] 10% vaporization temperature: 237 °C or higher, 90% vaporization temperature: 337 °C or lower

When the 10% vaporization temperature is lower than 237 °C, the after oil is easily vaporized, and the protective film is not stably formed. When the after oil is heated to the vaporization temperature using a heat source such as a heater if the 90% vaporization temperature is higher than 337 °C, a temperature difference tends to be large between a position close to the heat source and a position away from the heat source. As a result, the amount of the oil vaporized becomes unstable, and the protective film is not stably formed.

The vaporization temperature is a numerical value measured by a thermogravimetric measurement method based on JIS K0129 (2005). Specifically, a masking oil as a sample was put in an aluminum container (without a lid) of a thermogravimetry-differential thermal simultaneous measuring device (DTG-60H: manufactured by Shimadzu Corporation). Then, the temperature was increased from room temperature to 600 °C at a rate of 10 °C per minute, and a temperature when the mass of the after oil decreased by 10% and a temperature when the mass decreased by 90% were measured.

The after oil is preferably a paraffin oil among hydrocarbon-based oils. The same masking oil as the masking oil described above may be used. That is, a hydrocarbon-based oil (paraffin oil) that satisfies the condition 1 and the condition 2 may be used as the masking oil and the after oil.

A method for applying the after oil to the vapor deposition surface may be a flexographic printing method, a screen printing method, a gravure printing method, an offset printing method, a spraying method, a die coating method, or the like in addition to the vapor deposition method.

Next, results of comparative inspection of metalized films produced using after oils different from each other will be described.

### Example 11

A metalized film using, as an after oil, a hydrocarbon-based oil (paraffin oil) having a 10% vaporization temperature of 237 °C and a 90% vaporization temperature of 317 °C.

### Example 12

A metalized film using, as an after oil, a hydrocarbon-based oil (paraffin oil) having a 10% vaporization temperature of 265 °C and a 90% vaporization temperature of 337 °C.

### Comparative Example 11

A metalized film using, as an after oil, a hydrocarbon-based oil (paraffin oil) having a 10% vaporization temperature of 215 °C and a 90% vaporization temperature of 295 °C.

### Comparative Example 12

A metalized film using, as an after oil, a hydrocarbon-based oil (paraffin oil) having a 10% vaporization temperature of 253 °C and a 90% vaporization temperature of 358 °C.

A metalized film was produced under the same conditions except that the after oil was different in each of Examples and Comparative Examples. That is, a biaxially stretched polypropylene film having a length of 8000 m and a thickness of 2.5 μm was used as a dielectric film, and the surface of the biaxially stretched polypropylene film was subjected to corona treatment. A masking oil was adhered to the corona-treated surface by a flexographic printing method, and aluminum was then vapor-deposited to form a predetermined vapor deposition pattern. In the vapor deposition pattern, as shown in FIG. 1, margin portions (non-vapor deposition portions 4) are provided in a lattice shape, and adjacent divided electrodes 5 are connected to each other by fuse portions 6. The after oil filled in an oil tank was directly applied to the entire vapor deposition surface by heating and vaporing the after oil with a heater.

As an inspection, whether a stable protective film was formed was inspected. Specifically, first, a film capacitor having capacitance of 193 μF is produced by winding each of the metalized films of Example 11, Example 12, and Comparative Examples 11 and 12, and forming a metallikon electrode formed by spraying, for example, a metal at both axial ends. Next, each film capacitor was placed in an environment of 115 °C, and a voltage of 600 VDC was applied for 2000 hours. After a lapse of 2000 hours, each film capacitor was unwound, and a metalized film of 10 m was taken out from each film capacitor. The light transmission amount of the vapor deposition portion 3 in the film thickness direction of each metalized film was measured. The light transmission amount was measured using a light emitter and a light receiver (Fiber sensor FS-V21, FU-77V manufactured by KEYENCE CORPORATION).

TABLE 3

| | | | Comparative | Comparative |
|---|---|---|---|---|
| | Example 11 | Example 12 | Example 11 | Example 12 |
| Maximum | 3305 | 3282 | 3820 | 3942 |
| value | | | | |
| Minimum | 3022 | 3078 | 3080 | 3050 |
| value | | | | |

Table 3 shows the maximum and minimum values of the measured light transmission amount. When the vapor-deposited metal (vapor deposition portion 3) is deteriorated by moisture, the vapor-deposited metal turns colorless, and the light transmission amount increases. Therefore, as the difference between the maximum value and the minimum value of the light transmission amount is larger, unevenness occurs in the formation of the protective film. However, as shown in Table 3, in Example 11 and Example 12, the difference between the maximum value and the minimum value of the light transmission amount is less than that of Comparative Example 11 and Comparative Example 12. It can be seen that the protective film is formed with a substantially constant thickness, in other words, a stable protective film is formed.

The hydrocarbon-based oil has very low water vapor permeability. Therefore, when the stable protective film is formed, contact between the vapor deposition portion 3 and water vapor can be prevented, and the deterioration of the vapor deposition portion 3 can be suppressed.

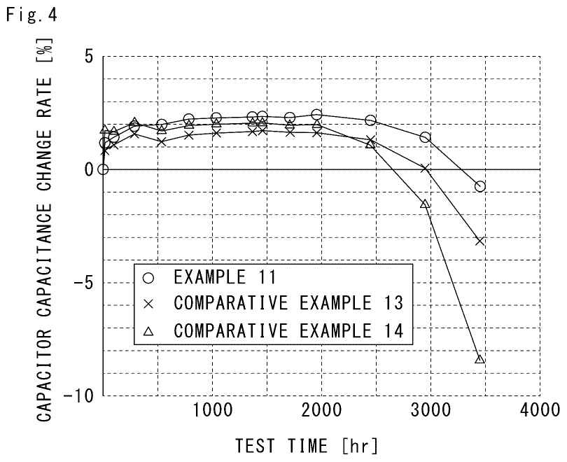

FIG. 4 is a graph showing the result of a moisture resistance load test. In a test method, a film capacitor is placed in an environment of 85 °C and a humidity of 85%, a voltage of 450 VDC is applied, and a change in capacitor capacitance after a lapse of a predetermined time is examined. In the drawing, “Example 11” refers to a film capacitor including the metalized film of Example 11, “Comparative Example 13” refers to a film capacitor including the metalized film of Example 11 except that a silicone oil having a 10% vaporization temperature of 193 °C and a 90% vaporization temperature of 264 °C is used as an after oil, and “Comparative Example 14” refers to a film capacitor including the metalized film of Example 11 except that the after oil is not applied.

As shown in the drawing, the capacitor capacitance after a lapse of about 3500 hours in Example 11 decreases only by about 0.7%, whereas the capacitor capacitance decreases by about 3.10% in Comparative Example 13. Therefore, it can be seen that high moisture resistance is obtained as compared with the case where the silicone oil is used as the after oil.

### REFERENCE SIGNS LIST

1 metalized film
2 dielectric film
3 vapor deposition portion
4 non-vapor deposition portion
5 divided electrode
6 fuse portion
7 masking oil layer
8 after oil layer (protective film)
A width dimension of margin portion
B width dimension of margin portion
C width dimension of fuse portion

1: A metalized film using a hydrocarbon-based oil having a 10% vaporization temperature of 237 °C or higher and a 90% vaporization temperature of 337 °C or lower as a masking oil or an after oil.

2: The metalized film according to claim 1, wherein a contact angle of the hydrocarbon-based oil with respect to a dielectric film is 17.9 to 22.8°.

3: The metalized film according to claim 1, wherein a contact angle of the hydrocarbon-based oil with respect to a polypropylene film is 17.9 to 22.8°.

4: A film capacitor comprising the metalized film according to claim 1.

5: A method for producing a metalized film according to claim 1, comprising the step of vaporizing and adhering the hydrocarbon-based oil.
